(19) United States
(12) Patent Application Publication
(10) Pub. No.: US 2004/0099959 A1
(43) Pub. Date: May 27, 2004

(54) Conductive bump structure

(75) Inventor: Pao-Yun Tang, Taoyuan Hsien (TW)

Correspondence Address: LOWE HAUPTMAN GOPSTEIN,, GILMAN & BERNER, LLP, Suite 310, 1700 Diagonal Road, Alexandria, VA, 22314, US

(73) Assignee: HannStar Display Corp.

(21) Appl. No.: 10/301,584

(22) Filed: Nov. 22, 2002

(51) Int. Cl. H01L 23/48; H01L 23/52; H01L 29/40

(52) U.S. Cl. 257/778; 257/738; 257/737

(57) ABSTRACT

The present invention describes a conductive bump structure. This structure comprises a buffer layer. The buffer layer manifests a deformation during bonding process. This deformation may compensate for the height difference among the gold bumps.

### FIELD OF THE INVENTION

The present invention relates to a structure of a conductive bump, and more specifically, to a structure of a conductive bump that compensates for a height difference among conductive bumps.

### BACKGROUND OF THE INVENTION

Fabrication of a liquid crystal display (LCD) panel involves a complicated process. In general, an LCD panel is formed by bonding a great number of driver chips and peripheral chips of controlling and driving circuits onto a glass plate or a glass panel with conductive paths formed thereover. Each LCD panel can have many LCD driver chips. The contacting pads on the chips must be bonded with correct alignment and high conductivity to corresponding conductive paths. The resulting LCD panel can be driven with correct signal and the image can be displayed on the LCD panel in a defect-free manner.

Various methods have been developed to achieve the above-described standard of alignment and conductivity. Two of the most frequently applied methods include the tape automated bonding (TAB) method and the chip-on-glass (COG) method. These methods, in addition to the bonding application in fabricating LCD panels, can also be applied on various kinds of chips to bond them on PCB or lead frames. With the development of conductive film, the density of chip contacts is raised without the drawback of undesired short circuits during the bonding process.

Referring to FIG. 1, a schematic cross-sectional view of the bonding process, the IC substrate 10, which is shown upside-down for illustrating the bonding process, has active devices formed thereover. In the application of a LCD driver chip as the IC substrate 10, gold conductive bumps 12 are formed over the IC substrate 10. In general, the gold conductive bumps 12 make conductive connections to the devices on the IC substrate 10 through aluminum pads (not shown). The pads are formed over the IC substrate 10 for making external connections. The IC substrate 10 is bonded to a glass plate 14 for forming an LCD panel. The gold conductive bumps 12 on the IC substrate 10 are bonded to the glass plate 14 with the conductive film 16 inserted between.

The conductive film 16 is typically a film containing adhesive resin and conductive particles. After the IC substrate 10 is placed on the glass plate 14 with accurate alignment, the IC substrate 10 is pressed under an elevated temperature. The pressing step enables the forming of conductive connections between each gold bump 12 and each conductive terminal 15 through conductive particle 18. The glass plate 14 and the IC substrate 10 are then tightly bonded with the hardened resin in the conductive film 16. The conventional bonding method with the gold conductive bump 12 is highly effective if alignment accuracy and the conductivity with the conductive film 16 bonding can be controlled well. The highly conductive characteristics of gold conductive bump 12 provide a low resistance connection for the terminals 15 on the glass plate 14 and the IC substrate 10.

The structure of the gold conductive bump 12 is shown in FIG. 2. A passivation layer 24 is formed around the aluminum pad 22 over the IC substrate 10. A gold conductive bump 12 is then formed over the aluminum pad 22. The gold conductive bump 12 comprises an under bump metallurgy 26 (UBM) and the gold bump 28. However, the application of the gold bump 12 is very difficult since gold has a high Young's modulus, about 110 GPa. Therefore, once a height difference exists among the gold conductive bumps 12 of the IC substrate 10, it is necessary to use a high pressure during the bonding process to compensate for the height difference and ensure the connection between the gold conductive bumps 12 and the conductive terminal 15 of the glass plate 14. However, the high pressure may cause the passivation layer 24 to break.

Typically, a composite bump structure is provided to solve the above-mentioned problem of the high Young's modulus of the gold conductive bump. The composite bump structure is shown in FIG. 3. A polymer layer 30 is first formed over the aluminum pad 22. Because the polymer layer 30 is non-conductive, the polymer layer 30 does not completely cover the aluminum pad 22. Next, a thin metal film 38 comprising an adhesive layer 32, a barrier layer 34 and a conductive layer 36 is formed over the surface of the polymer layer 30. However, because of the thin metal film 38, this structure may generate some inherent problems. First, the probe test process often breaks the thin metal film 38. This situation increases the process cost. Second, the polymer layer 30 is formed on the center of the aluminum pad 22. Then, the thin metal film 38 is formed over it. Therefore, compared with the gold conductive bump, the conductive area is reduced. Moreover, breakage often occurs in regions 42 and 44.

In light of the above, the conventional gold conductive bump structure with a high Young's modulus often causes the aluminum pad to break during the bonding process. On the other hand, the composite bump structure used to resolve the high Young's modulus often causes the thin metal film to break during a probe test. This situation affects the electrical conductivity.

### SUMMARY OF THE INVENTION

In accordance with the foregoing description, the conventional gold conductive bump structure with a high Young's modulus requires a high pressure during the bonding process to ensure the connection between the gold conductive bumps and the conductive terminal of the glass. However, the high pressure may cause the passivation layer to break. On the other hand, the composite bump structure used to resolve the high Young's modulus often causes the thin metal film to break during a probe test. This situation affects the electrical conductivity. Therefore, a gold bump structure with low Young's modulus and a thicker metal layer is required.

The main purpose of the present invention is to provide a structure of a conductive bump.

Another purpose of the present invention is to disclose a structure of a conductive bump needed in the bonding process of LCD driver chips and a glass panel.

A further purpose of the present invention is to provide a structure of a conductive bump that compensates for the height difference among the conductive bumps.

The present invention provides a conductive bump structure. This structure comprises a buffer layer. A deformation of the buffer layer may occur during the bonding process. This deformation may compensate for the height difference among the gold bumps that may cause an electrical conductivity problem during the bonding process. A under bump metallurgy is formed over the buffer layer. The under bump metallurgy comprises an adhesion layer, a wetting layer and a protective layer. Next, a gold bump is formed over the under bump metallurgy. In accordance with the present invention, the conductive bump comprising a low Young's modulus buffer layer efficiently distribute pressure during the bonding process to control the connection resistance variation.

### BRIEF DESCRIPTION OF THE DRAWINGS

The foregoing aspects and many of the attendant advantages of this invention will become more readily appreciated and better understood by referencing the following detailed description, when taken in conjunction with the accompanying drawings, wherein:

FIG. 1 illustrates a schematic cross-sectional view of a bonding process between an IC substrate and a glass plate;

FIG. 2 illustrates a schematic cross-sectional view of a conventional gold conductive bump;

FIG. 3 illustrates a schematic cross-sectional view of a conventional composite bump;

FIG. 4 illustrates a schematic view of a bonding process between an the LCD driver chips and a glass plate;

FIG. 5 illustrates a schematic cross-sectional view of an IC substrate with a conductive pad formed thereover in accordance with the present invention;

FIG. 6 illustrates a schematic cross-sectional view of forming a buffer layer over the IC substrate in accordance with the present invention;

FIG. 7 illustrates a schematic cross-sectional view of forming a photoresist layer and defining the buffer layer in accordance with the present invention;

FIG. 8 illustrates a schematic cross-sectional view of forming the under bump metallurgy and the gold bump in accordance with the present invention;

FIG. 9 illustrates a schematic cross-sectional view of removing the under bump metallurgy and the bufer layer not being covered by the gold bump in accordance with the present invention;

FIG. 10 illustrates a schematic cross-sectional view of bonding the IC substrate to a glass plate in accordance with the present invention; and

FIG. 11 illustrates a schematic cross-sectional view of the gold bump in accordance with the second embodiment of the present invention.

### DETAILED DESCRIPTION OF THE PREFERRED EMBODIMENT

Without limiting the spirit and scope of the present invention, the conductive bump structure proposed in the present invention is illustrated with one preferred embodiment. Skilled artisans, upon acknowledging the embodiment, can apply the conductive bump structure of the present invention to any kind of bonding process. In accordance with the structure of the present invention, the conductive bump comprising a low Young's modulus buffer layer efficiently distributes pressure during the bonding process to avoid breaking the passivation layer. The embodiment described below is solely given as an illustrative example.

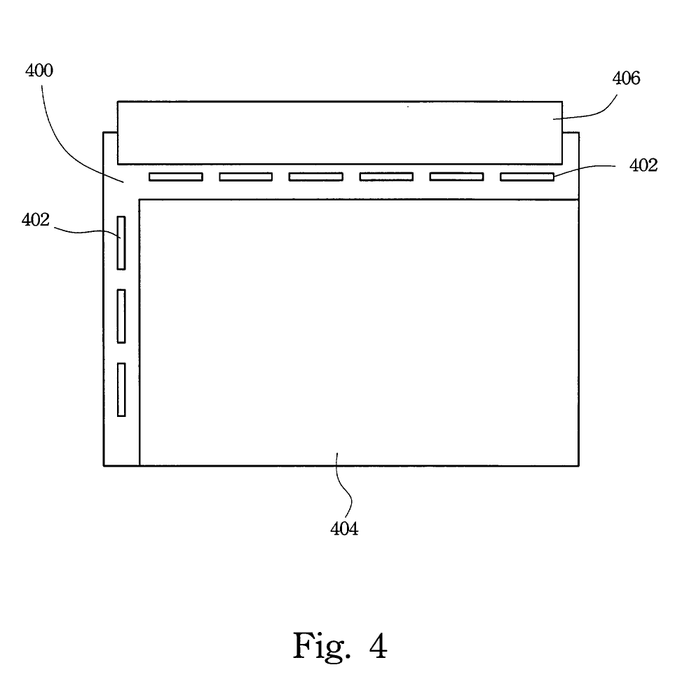

The present invention discloses a conductive bump structure. In the preferred embodiment, the structure is applied for bonding LCD driver chips 402 to a glass substrate 400 to drive the LCD panel 404 as shown in the FIG. 4. The LCD driver chips 402 is connected with the peripheral circuit 406. The gold bump structure provided by the prior art can be replaced with this structure having a low Young's modulus. The structure of the present invention is employed for improving the characteristics of conductive bumps.

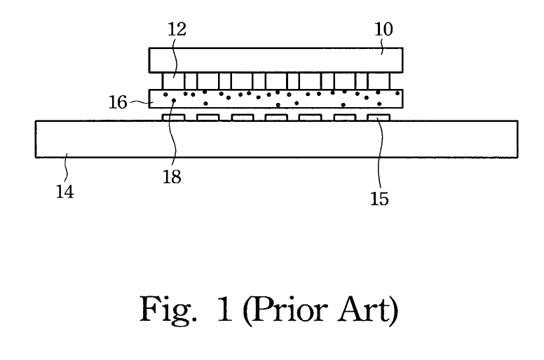

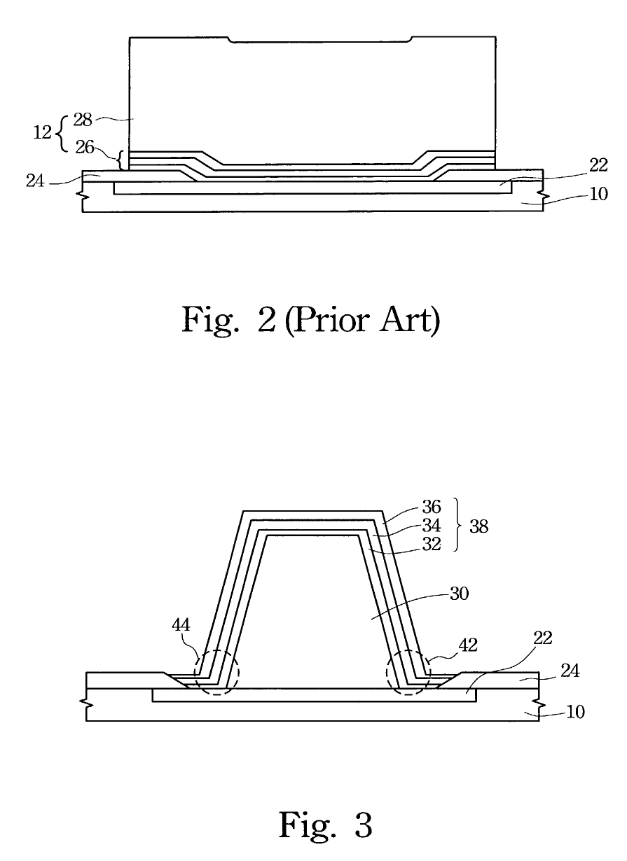

Referring to the cross-sectional view of the bonding process in FIG. 1, the gold conductive bumps 12 on the IC substrate 10 are bonded to the glass plate 14 with the conductive film 16 inserted between. In general, a specified pressure must be applied onto the conductive film 16 through the gold conductive bumps 12 to form the conductive connections between each gold conductive bumps 12 and each conductive terminal 15. For forming perfect connections without undesired electrical conductive problem, the gold conductive bumps 12 shown in the FIG. 1 must be formed with the same height, or the high Young's modulus of the gold conductive bumps 12 may cause inherent problems, such as the passivation layer breaking. The Young's modulus may be described as follows.

F=K×S

“K” is Young's modulus. “F” is the applied pressure during the bonding process. “S” is the deformation level of the whole IC substrate when pressure is applied to the IC substrate.

The high Young's modulus of the gold conductive bumps 12 means that a high applied pressure is necessary to help these bumps with different heights form perfect connections with the conductive terminal 15. The high applied pressure may cause a deformation of the IC substrate 10 during the bonding process. This kind of deformation may affect the passivation layer, and even break the passivation layer. Therefore, the conductive bump structure with a low Young's modulus is described as follows.

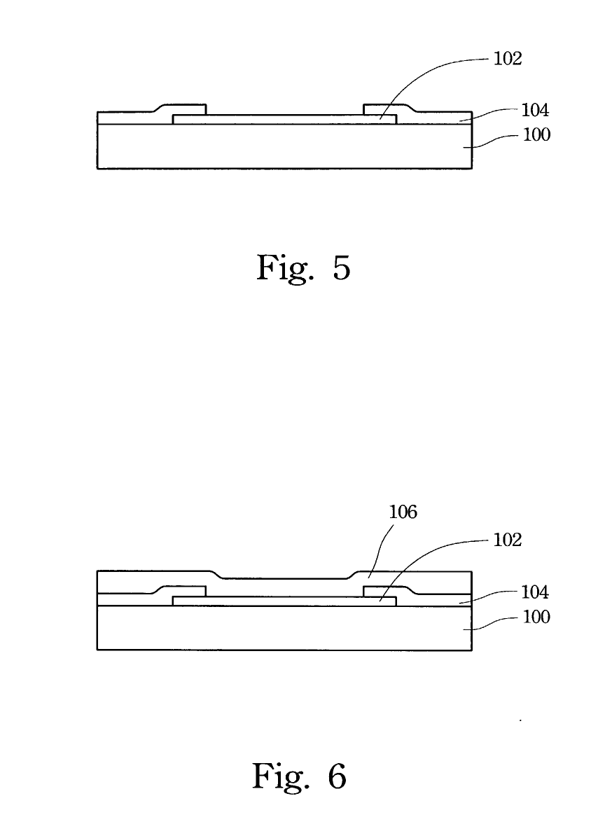

Referring to the cross-sectional view in FIG. 5, an IC substrate 100 is provided with a conductive pad 102 formed thereover. The IC substrate 100 can be, for example, an LCD (liquid crystal display) driver chip which is finished with the devices formed thereover and has conductive pad 102 for making external connections. The IC substrate 100 can also be other kinds of chips for forming bumps to make external connections or bondings. The conductive pad 102 can be surrounded by a passivation layer 104. The passivation layer 104 protects the IC substrate 100. In most of the applications, the conductive pad 102 can be an aluminum pad and the passivation layer 104 can be dielectric materials like silicon nitride or silicon oxide.

Next, FIG. 6 shows the conductive bump structure of the present invention. A barrier layer 106 is formed over the IC substrate 100. The barrier layer 106 can be formed by a polymer material, such as a polyimide. This main purpose of the barrier layer 106 is to connect with the gold bump formed later to reduce the Young's modulus of the whole conductive bump structure. This conductive bump structure of the present invention uses this buffer layer 106 to cause a deformation during the bonding process. This deformation compensates for the height difference among the conductive bumps that may cause an electrical conductivity problem during the bonding process. Therefore, it is not necessary to require a high applied pressure to ensure a perfect conductive connections forming between each conductive bump and each conductive terminal of the substrate. The low applied pressure may reduce the risk of breaking the passivation layer 104 over the IC substrate 100. The buffer layer 106 is formed by, for example, spin coating. The thickness of the buffer layer 106 is at least about 5 micrometers.

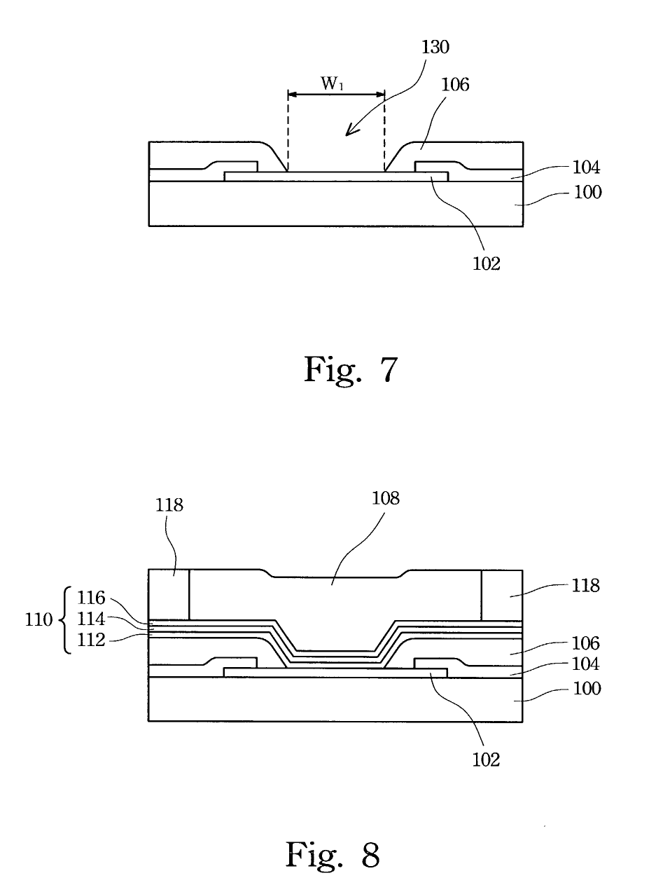

In general, the buffer layer is made of a non-conductive material. Therefore, the conductive pad 102 covered by the buffer layer 106 needs to be exposed to connect with the gold bump formed later. Referring to FIG. 7, a photoresist layer is formed over the buffer layer 106 and a bump opening 130 is defined in the photoresist layer. The bump opening 130 is defined right over the conductive pad 102, and the width of the opening 130 is W1. Next, the buffer layer 106 is etched using the defined photoresist layer as a mask. The etching method uses wet etching or dry etching. Finally, as shown in FIG. 7, the photoresist layer is removed.

A gold conductive bump is then formed over the conductive pad 102 and the buffer layer 106. FIG. 8 shows a structure diagram of the gold conductive bump. When performing a flip chip process, a gold conductive bump first is formed over the IC substrate 100. The gold conductive bump comprises under bump metallurgy 110 and the gold bump 108. In general, the under bump metallurgy 110 comprises three metal layers, the adhesion layer 112, the wetting layer 114 and the conductive layer 116. The main purpose of the adhesion layer 112 is to allow the gold bump 108 to adhere well to the buffer layer 106 and the conductive pad 102. The adhesion layer 112 is made from a material such as tungsten, titanium or chromium. The wetting layer 114 is made from a material such as nickel or copper. The conductive layer 116 is then formed over the wetting layer 114. The under bump metallurgy 110 is formed by, for example, sputtering or evaporation.

Referring to FIG. 8 again, a gold bump 108 is formed over the under bump metallurgy 110 and the conductive pad 102. A electrical connection between the gold bump 108 and the conductive pad 102 is made through the under bump metallurgy 110. The gold bump 108 over the under bump metallurgy 110 is formed by, for example, electroplating. The process of forming the gold bump 108 includes the following steps. First, a photoresist layer 118 is formed over the under bump metallurgy 110. Then, a bump opening is defined in the photoresist layer 118. Next, the gold bump 108 is formed over the under bump metallurgy 110 within the bump opening. Finally, the photoresist layer 118 is removed.

The gold bump 108 is conformally formed to the profile of the under bump metallurgy 110. With the slightly raised height of the under bump metallurgy 110 at the edge and the highly planar region of the conductive pad 102, the gold bump 108 can be formed with an extended planar region in most of the area and a slightly raised edge, as illustrated by the profile shown in FIG. 7.

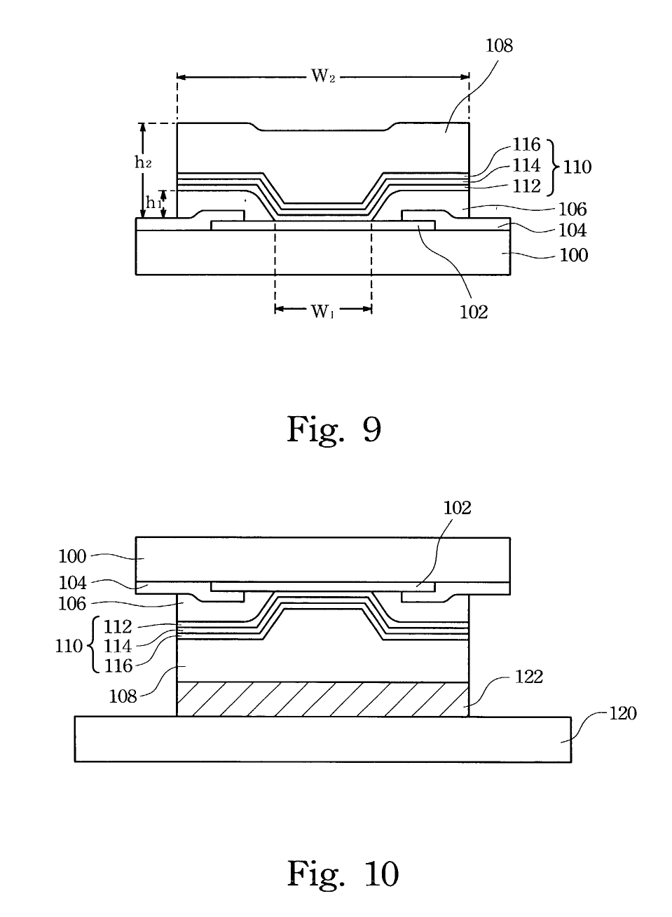

Referring to FIG. 9, a portion of the under bump metallurgy 110 and the buffer layer 106 uncovered by the gold bump 108 is then removed. Removal is performed by, for example, an etching process employing the gold bump 108 as a mask. It is noted that the width of the buffer layer 106 located in the conductive pad 102 is W₁. The width of the conductive pad 102 located in the passivation layer 104 is W₂. The ratio of W₁ to W₂ is shown in the follows.

The ratio of W₁ to W₂ is shown in the follows.

1/3≦W₁/W₂≦2/3

On the other hand, the height of the buffer layer 106 over the conductive layer 102 is H₁. The total height of the buffer layer 106, the under bump metallurgy 110 and the gold bump 108 over the conductive layer 102 is H₂. In accordance with the present invention, the Young's modulus can be reduced efficiently only if the ratio of the H₁ to H₂ is at least about 1/3. In this situation, the buffer layer manifests a deformation during the bonding process. This deformation compensates for the height difference among the gold bumps that may cause an electrical conductivity problem during the bonding process.

Referring to FIG. 10, after the gold bump 108 is formed over the IC substrate 100, the IC substrate 100 can then be bonded to a glass plate 120. The IC substrate 100 is illustrated in FIG. 10, where IC substrate 100 is upside-down for a clear illustration. A conductive film 122 is placed between the IC substrate 100 and the glass plate 120 to form conductive connections.

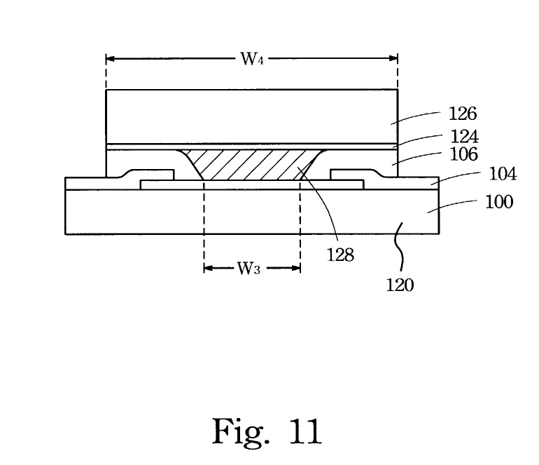

Referring to FIG. 11, it shows the second embodiment of the present invention. An IC substrate 100 is provided with a conductive pad 102 formed thereover. The conductive pad 102 can be surrounded by a passivation layer 104. The passivation layer 104 protects the IC substrate 100. Next, a buffer layer 106 is formed over the IC substrate 100. A photolithography technology is performed to pattern the buffer layer 106.

A nickel (Ni) metal layer 128 is formed on the patterned buffer ayer 106 by electroless plating, then, a etching step or a CMP step is performed to remove the Ni metal over the buffer layer 106 to form a flat surface. A sputtering technology is performed to form a Au layer 124 to serve as a adhering layer. Finally, a gold bump 126 is formed over the Au layer 124 by the electroplated technology. In this structure, there is no any height difference in the surface of the gold bump 126 because of the flat surface. Such structure may improve the process of bonding with the glass substrate.

On the other hand, the width of the buffer layer 106 located in the conductive pad 102 is W₃. The width of the conductive pad 102 located in the passivation layer 104 is W₄. The ratio of W₃ to W₄ is shown in the follows.

1/3≦W₃/W₄≦2/3

The whole Young's modulus of the conductive bump structure provided by the present invention may be reduced because this structure includes a buffer layer with a low Young's modulus. The buffer layer undergoes a deformation during the bonding process. This deformation compensates for the height difference among the conductive bumps that may cause the electrical conductivity problem during the bonding process.

As is understood by a person skilled in the art, the foregoing descriptions of the preferred embodiment of the present invention are an illustration of the present invention rather than a limitation thereof. It is intended to cover various modifications and similar arrangements included within the spirit and scope of the appended claims. The scope of the claims should be accorded to the broadest interpretation so as to encompass all such modifications and similar structures. While a preferred embodiment of the invention has been illustrated and described, it will be appreciated that various changes can be made therein without departing from the spirit and scope of the invention.

What is claimed is:

1. A conductive bump structure, said structure being formed over a conductive pad of an IC substrate, wherein said conductive pad is covered by a passivation layer with a first opening and said conductive pad is partially exposed by said opening, said structure comprising:
a buffer layer with a second opening formed over said passivation layer and said conductive layer, wherein said second opening is smaller than said first opening and located at a center of said first opening to expose partially said conductive pad, and a thickness ratio of said buffer layer to said conductive bump structure is at least about 1/3;
an under bump metallurgy formed over said buffer layer and said conductive pad; and
a gold bump formed over said under bump metallurgy.

2. The conductive bump structure of claim 1, wherein a ratio of said second opening (W2) to said first opening (W1) is about 1/3≦W₁/W₂≦2/3.

3. The conductive bump structure of claim 1, wherein said conductive pad is an aluminum pad.

4. The conductive bump structure of claim 1, wherein said buffer layer is a polyimide.

5. The conductive bump structure of claim 1, wherein said buffer layer is formed by spin coating.

6. The conductive bump structure of claim 1, wherein said second opening is formed by wet etching or dry etching said buffer layer.

7. The conductive bump structure of claim 1, wherein said under bump metallurgy comprises a adhesion layer, a wetting layer and a conductive layer.

8. The conductive bump structure of claim 7, wherein said adhesion layer is made of tungsten, titanium or chromium.

9. The conductive bump structure of claim 7, wherein the wetting layer is made of nickel or copper.

10. The conductive bump structure of claim 1, wherein said under bump metallurgy comprises a adhesion layer and a conductive layer.

11. The conductive bump structure of claim 10, wherein the adhesion layer is made of gold (Au).

12. The conductive bump structure of claim 10, wherein the conductive layer is made of nickle (Ni).

13. The conductive bump structure of claim 10, wherein the conductive layer is formed by Electroless plating technology.

14. A conductive bump structure, said structure being formed over a conductive pad of an IC substrate, wherein said conductive pad is covered by a passivation layer with a first opening and said conductive pad is partially exposed through said opening, said structure comprising:
a buffer layer with a second opening formed over said passivation layer and said conductive pad, wherein said second opening is smaller than said first opening and located at a center of said first opening to expose partially said conductive pad, and a thickness ratio of said buffer layer to said conductive bump structure is at least about 1/3 and a ratio of said second opening to said first opening is about 1/3≦W₁/W₂≦2/3;
an under bump metallurgy formed over said buffer layer and said conductive pad; and
a gold bump formed over said under bump metallurgy.

15. The conductive bump structure of claim 14, wherein said conductive pad is an aluminum pad.

16. The conductive bump structure of claim 14, wherein said buffer layer is a polyimide.

17. The conductive bump structure of claim 14, wherein said buffer layer is formed by spin coating.

18. The conductive bump structure of claim 14, wherein said second opening is formed by wet etching or dry etching said buffer layer.

19. The conductive bump structure of claim 14, wherein said under bump metallurgy comprises an adhesion layer, a wetting layer and a conductive layer.

20. The conductive bump structure of claim 19, wherein said adhesion layer is made of tungsten, titanium or chromium.

21. The conductive bump structure of claim 19, wherein the wetting layer is nickel or copper.

22. The conductive bump structure of claim 14, wherein said under bump metallurgy comprises a adhesion layer and a conductive layer.

23. The conductive bump structure of claim 22, wherein the adhesion layer is made of gold (Au).

24. The conductive bump structure of claim 22, wherein the conductive layer is made of nickle (Ni).

25. The conductive bump structure of claim 22, wherein the conductive layer is formed by Electroless plating technology.

26. A conductive bump structure, said structure being formed over a conductive pad of an IC substrate, wherein said conductive pad is covered by a passivation layer with a first opening and said conductive pad is partially exposed through said opening, said structure comprising:
a polyimide layer with a second opening formed over said passivation layer and said conductive pad, wherein said second opening is smaller than said first opening and located at a center of said first opening to expose partially said conductive pad, wherein a thickness ratio of said polyimide layer to said conductive bump structure is at least about 1/3 and a ratio of said second opening to said first opening is about 1/3≦W₁/W₂≦2/3;
an under bump metallurgy formed over said polyimide layer and said conductive pad; and
a gold bump formed over said under bump metallurgy.

27. The conductive bump structure of claim 26, wherein said conductive pad is an aluminum pad.

28. The conductive bump structure of claim 26, wherein said polyimide layer is formed by spin coating.

29. The conductive bump structure of claim 26, wherein said second opening is formed by wet etching or dry etching said buffer layer.

30. The conductive bump structure of claim 26, wherein said under bump metallurgy comprises an adhesion layer, a wetting layer and a conductive layer.

31. The conductive bump structure of claim 30, wherein said adhesion layer is made of tungsten, titanium or chromium.

32. The conductive bump structure of claim 30, wherein the wetting layer is made of nickel or copper.

33. The conductive bump structure of claim 26, wherein said under bump metallurgy comprises a adhesion layer and a conductive layer.

34. The conductive bump structure of claim 33, wherein the adhesion layer is made of gold (Au).

35. The conductive bump structure of claim 33, wherein the conductive layer is made of nickle (Ni).

36. The conductive bump structure of claim 33, wherein the conductive layer is formed by Electroless plating technology.
